(19) United States
(12) Patent Application Publication
(10) Pub. No.: US 2024/0149742 A1
(43) Pub. Date: May 9, 2024

(54) SOP MANAGEMENT METHOD AND APPARATUS FOR POWER BATTERY PACK, AND ELECTRIC VEHICLE

(71) Applicants: Microvast Power Systems Co., Ltd., Huzhou (CN); Microvast, Inc., Stafford, TX (US)

(72) Inventors: Zhenfei YAO, Huzhou (CN); Shengxian WU, Huzhou (CN); Ruijing ZHANG, Huzhou (CN); Wenhao XU, Huzhou (CN)

(73) Assignees: Microvast Power Systems Co., Ltd., Huzhou (CN); Microvast, Inc., Stafford, TX (US)

(21) Appl. No.: 18/275,023

(22) PCT Filed: Feb. 1, 2021
(86) PCT No.: PCT/CN2021/074659

§ 371 Date: Jan. 14, 2024

(51) Int. Cl. B60L 58/12; B60L 3/00; B60L 3/04; G01R 31/367; G01R 31/3835; H02J 7/00

(52) U.S. Cl. CPC B60L 58/12; B60L 3/0046; B60L 3/04; G01R 31/367; G01R 31/3835; H02J 7/00304; H02J 7/0031; H02J 7/0048; H02J 7/00714

(57) ABSTRACT

Provided are an SOP management method and apparatus for a power battery pack, and an electric vehicle. The SOP management method includes: obtaining a SOP value of each parallel battery branch in a power battery pack; and obtaining a current total SOP value of the power battery pack according to the SOP value of each parallel battery branch. In the present application, in a multi-branch-parallel power battery pack, an SOP value of each parallel branch is first subjected to refined estimation according to an operation condition of each parallel branch, and then the total SOP of the power battery pack is estimated from the whole system level, and the problem of statistical distortion of the total SOP of the power battery pack is solved, thereby effectively improving the safety and stability of use of the battery.

### TECHNICAL FIELD

The present application relates to the field of electric vehicle battery management, in particular to an SOP management method for a power battery pack, an SOP management apparatus for the power battery pack, and an electric vehicle.

### BACKGROUND

The power battery pack can provide the power for the operation of electric vehicles, and is an important part of electric vehicles. The power battery pack with multiple parallel battery branches includes multiple parallel battery modules, each battery module is composed of multiple cells, and each parallel branch is connected with the load on the outside through the corresponding relay, and the load can be disconnected or connected through the control relay.

The SOP (State of Power) of the power battery is an important parameter for the safety control and energy recovery of electric vehicles, which directly reflects the peak charge and discharge power of the current battery system. When starting, accelerating, or braking the vehicle, the SOP directly affects the vehicle's quick start ability, rapid acceleration ability and emergency braking energy recovery ability. Therefore, the accurate management of SOP determines the safety and reliability of the entire vehicle during operation. For example, it can absorb as much feedback energy as possible while braking without harming the battery, and provide more power to obtain greater acceleration while accelerating without harming the battery. At the same time, it can ensure that the vehicle will not lose power due to under voltage or over current protection even when driving in a very low state of charge.

### SUMMARY OF THE PRESENT APPLICATION

### Technical Problem

The existing SOP estimation method usually only considers the estimation at the system level, and does not consider the distinction between the master and slave, that is, does not consider to distinguish between the separate estimation of each parallel battery branch and the estimation at the system level of the whole power battery pack. For multi-branch parallel power battery packs, this lack of master-slave distinction directly leads to the distortion of SOP estimation, which affects the performance of the battery management system and the safety and stability of the battery system.

### Solution of the Problem

### Technical Solution

The purpose of the present application is to provide an SOP management method for power battery packs, an SOP management apparatus for power battery packs and an electric vehicle, which can better estimate the SOP of the power battery pack, provide more reliable and effective information support for the power distribution and energy control of the vehicle system, and take into account the energy economy while ensuring the running performance of the vehicle.

In order to solve the above-mentioned technical problems, the present application provides an SOP management method for the power battery pack, as one of the embodiments, the SOP management method for the power battery pack includes:
obtaining an SOP value of each parallel battery branch in the power battery pack;
obtaining a current total SOP value of the power battery pack according to the SOP value of each parallel battery branch.

In one embodiment, the step of obtaining the SOP value of each parallel battery branch in the power battery pack includes:
obtaining an operating condition of the each parallel battery branch;
obtaining the SOP value of the each parallel battery branch according to the operating condition and a corresponding SOP value reference table.

In one embodiment, the step of obtaining the SOP value of the each parallel battery branch according to the operating condition and the corresponding SOP value reference table includes:
obtaining an initial SOP value of the each parallel battery branch according to the operating condition and the corresponding SOP value reference table;
obtaining a fault level of each parallel battery branch;
performing power limiting processing on the initial SOP value of the each parallel battery branch according to the fault level of the each parallel battery branch, so as to obtain the SOP value of the each parallel battery branch.

In one embodiment, the step of obtaining the fault level of the each parallel battery branch includes:
obtaining battery a temperature and a battery voltage of the each parallel battery branch;
obtaining the fault level of the each parallel battery branch according to the battery temperature and the battery voltage of the each parallel battery branch.

In one embodiment, the step of obtaining the current total SOP value of the power battery pack according to the SOP value of the each parallel battery branch includes:
obtaining the minimum value in the SOP value of the each parallel battery branch;
obtaining the current total SOP value of the power battery pack according to the minimum value of the SOP value of the each parallel battery branch and number of the parallel branches in the power battery pack.

In one embodiment, the step of obtaining the current total SOP value of the power battery pack according to the minimum value of the SOP value of the each parallel battery branch and the number of the parallel branches in the power battery pack includes:
obtaining a first target total SOP value of the power battery pack through multiplying the minimum SOP value of the each parallel battery branch with the number of the parallel branches of the power battery pack;
obtaining the current total SOP value of the power battery pack through filtering a last total SOP value of the power battery pack according to the first target total SOP value of the power battery pack.

In one embodiment, a filtering process formula of filtering the last total SOP value of the power battery pack according to the first target total SOP value of the power battery pack is:

Z=δ*Z₀+(1−δ)*Z₁
where, Z is the current total SOP value of the power battery pack, Z₀ is a current first target total SOP value of the power battery pack, Z₁ is the last total SOP value of the power battery pack, and δ is a preset coefficient.

In one embodiment, after the step of obtaining the current total SOP value of the power battery pack according to the minimum value of the SOP values of the each parallel battery branch and the number of the parallel branches in the power battery pack, the method further includes:
outputting the current total SOP value of the power battery pack;
determining whether accumulated time is greater than a preset value;
when the accumulated time is greater than the preset value, determining whether the power battery pack has a parallel battery branch with serious faults;
when there is a parallel battery branch with serious faults in the power battery pack, controlling the parallel battery branch with serious faults to be disconnected and powered off, and controlling remaining parallel battery branches to output a preset total SOP value.

In one embodiment, the SOP management method for the power battery pack further includes:
obtaining a fault level of the power battery pack when there is no parallel battery branch with serious faults in the power battery pack;
obtaining a second target total SOP value according to the minimum value of SOP values of online parallel battery branches and number of the online parallel battery branches;
performing power limiting processing on the second target total SOP value according to the fault level of the power battery pack to obtain an updated second target total SOP value;
obtaining the current total SOP value of the power battery pack through perform a corresponding filtering process on a last total SOP value of the power battery pack according to the updated second target total SOP value.

In one embodiment, the SOP management method for the power battery pack further includes:
obtaining a real-time charge and discharge current of the each parallel battery branch in the power battery pack;
adjusting the output of the parallel battery branch to the current SOP value of the branch, when the real-time charge and discharge current of one of the parallel battery branches is in an abnormal state, where the abnormal state includes that time period, during which the real-time charge and discharge current is greater than the SOP value of the branch under current parameter condition, reaches the first time value; or includes that time period, during which the real-time charge and discharge current is less than a preset ratio of the SOP value of the branch under the current parameter condition, reaches the second time value.

In order to solve the above-mentioned technical problems, the present application also provides an SOP management apparatus for the power battery pack, as an embodiment, the SOP management apparatus of the power battery pack includes a primary battery management unit and a plurality of secondary battery management units. The primary battery management unit and the plurality of secondary battery management units are connected in communication, where,
each secondary battery management unit is configured to obtain an SOP value of the corresponding parallel battery branch in the power battery pack and send it to the primary battery management unit;
the primary battery management unit is configured to obtain a current total SOP value of the power battery pack according to the SOP value of each parallel battery branch.

In order to solve the above technical problem, the present application also provides an electric vehicle, as one of the embodiments, the electric vehicle includes the SOP management apparatus of the power battery pack according to any one of the above embodiments.

### Beneficial Effect of the Present Application

### Beneficial Effect

The SOP management method for the power battery pack provided in the present application, the SOP management apparatus for the power battery pack applying the SOP management method for the power battery pack, and the electric vehicle are to estimate in detail the SOP value of each parallel battery branch based on the operating conditions of each parallel battery branch in the multi-branch parallel power battery pack, and then to estimate the total SOP of the power battery pack at the whole system level. Thus the present application can solve the problem of the total SOP statistical distortion of the power battery pack through the master-slave differentiation, so as to improve the vehicle performance, avoid the power battery-triggered operation failure, and extend the life of the power battery.

### BRIEF DESCRIPTION OF THE DRAWINGS

### Description of the Drawings

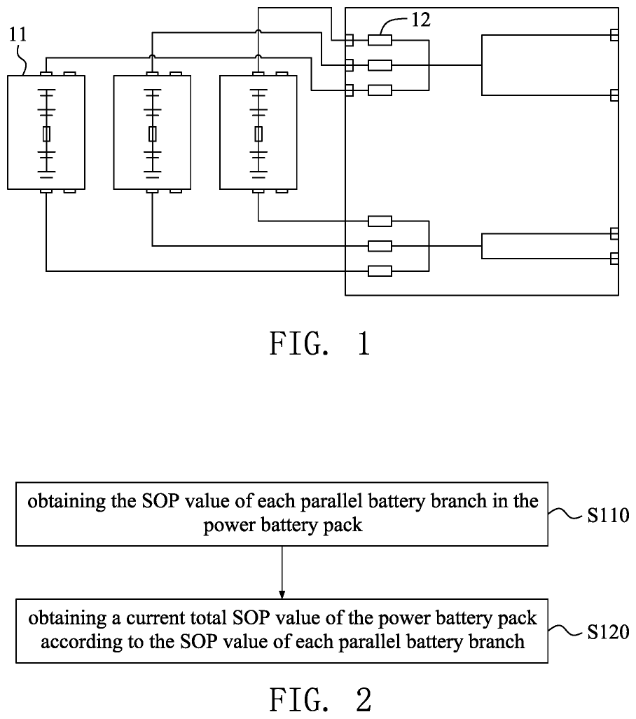

FIG. 1 is a schematic diagram of the power output of a multi-parallel battery branch for the power battery pack of the present application.

FIG. 2 is a schematic flowchart of an SOP management method for the power battery pack according to a first embodiment of the present application.

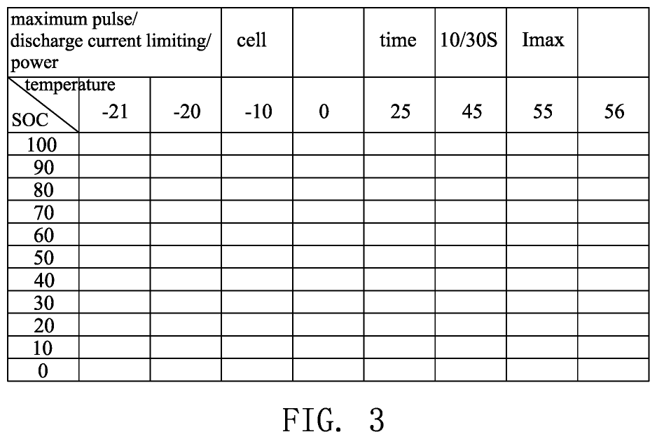

FIG. 3 is a corresponding SOP reference table for the three parameters of temperature, SOC and time in the embodiments of the present application.

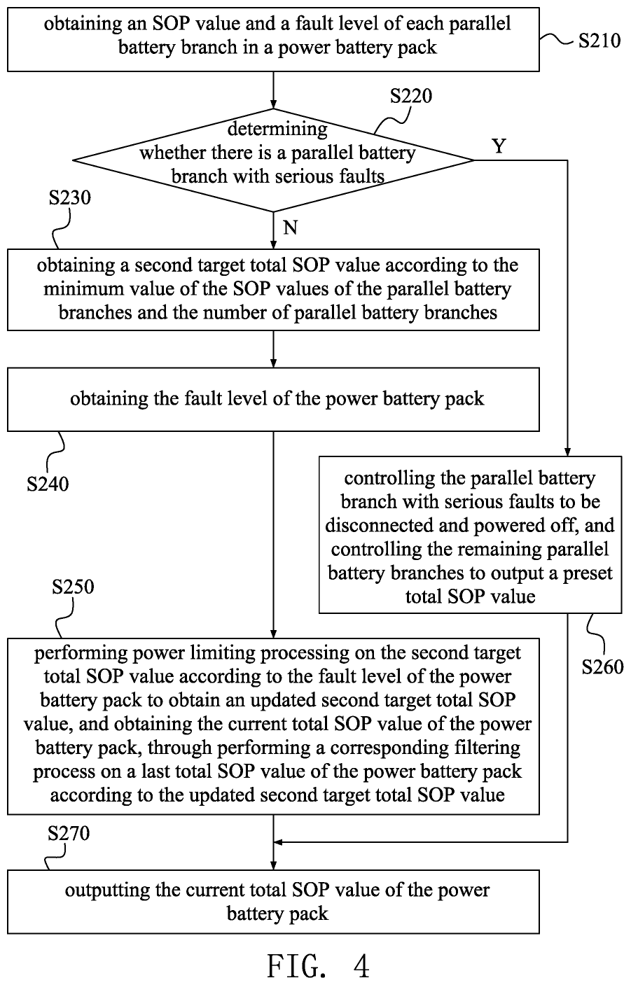

FIG. 4 is a schematic flowchart of an SOP management method for the power battery pack according to a second embodiment of the present application.

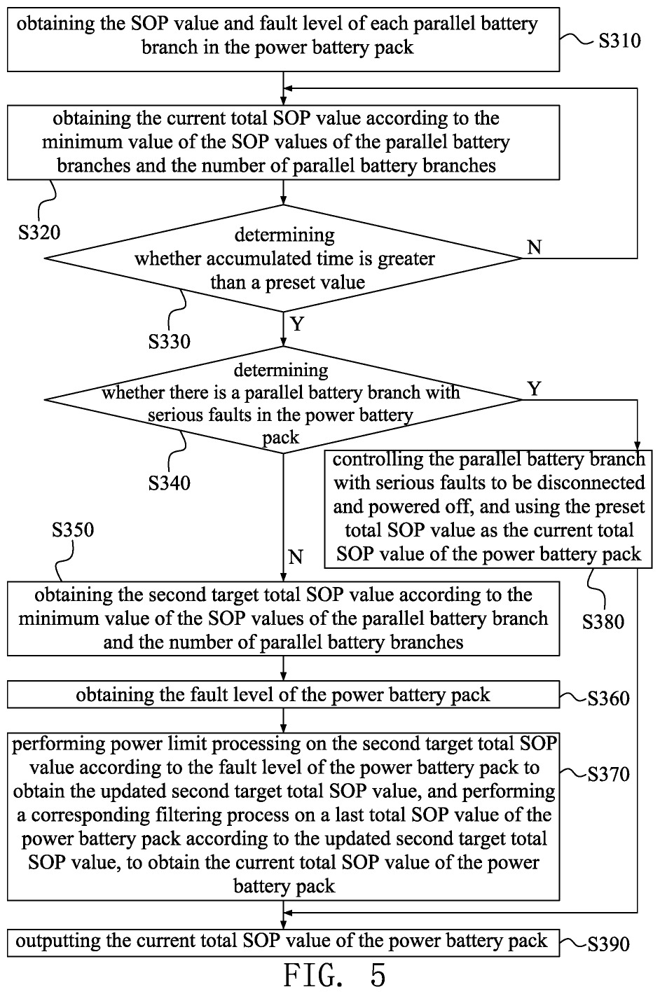

FIG. 5 is a schematic flowchart of an SOP management method for the power battery pack according to a third embodiment of the present application.

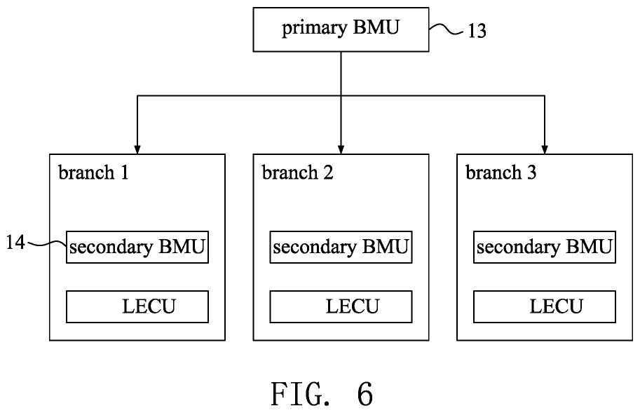

FIG. 6 is a schematic structural diagram of the SOP management apparatus for the power battery pack of the present application.

### DETAILED DESCRIPTION OF THE PRESENT APPLICATION

### Description of Embodiments

The embodiments of the present application are described below by specific examples, and those skilled in the art can easily understand other advantages and effects of the present application from the contents disclosed in this specification.

In the following description, reference is made to the accompanying drawings, which describe several embodiments of the present application. It is to be understood that other embodiments may be utilized and mechanical, structural, electrical, as well as operational changes may be made without departing from the spirit and scope of the present application. The following detailed description should not be considered limiting, and the scope of embodiments of the present application is limited only by the claims of the issued patent. The terminology used herein is for the purpose of describing particular embodiments only and is not intended to limit the present application. Although in some instances the terms first, second, etc. are used herein to describe various elements, these elements should not be limited by these terms. These terms are only used to distinguish one element from another.

Also, as used herein, the singular forms “a,” “an,” and “the” are intended to include the plural forms as well, unless the context dictates otherwise. It should be further understood that the terms “comprising”, “including” indicate the presence of stated features, steps, operations, elements, components, items, categories, and/or groups, but do not exclude the presence, appearance or addition of one or more other features, steps, operations, elements, components, items, categories, and/or groups. The terms “or” and “and/or” as used herein are to be construed to be inclusive or to mean any one or any combination. Thus, “A, B or C” or “A, B and/or C” means “any of the following: A; B; C; A and B; A and C; B and C; A, B and C”. Exceptions to this definition arise only when combinations of elements, functions, steps, or operations are inherently mutually exclusive in some way.

Please refer to FIG. 1. FIG. 1 is a schematic diagram of the power output of the multi-parallel battery branch for the power battery pack of the present application. As shown in FIG. 1, the power battery pack includes a plurality of parallel battery branches 11, each parallel battery branch 11 includes a plurality of cells, and each parallel battery branch is connected to an external load through a relay 12. The load can be disconnected or connected. In the present application, the SOP value of each parallel battery branch is estimated in detail, on the basis of which the total SOP value of the whole system level is estimated. Through this method, it can not only improve the performance of the whole vehicle, avoid the power battery-triggered operation failure, but also extend the life of the power battery.

It is worth mentioning that FIG. 1, as an example, only shows three parallel battery branches 11, which is only used to describe the application scenario, and the number of parallel battery branches is not limited and can be any number.

On the basis of the description of the above application scenarios, the SOP management method for the power battery pack of the present application will be described in detail below with reference to the relevant drawings.

### First Embodiment

Please refer to FIG. 2, which is a schematic flowchart of the SOP management method for the power battery pack according to the first embodiment of the present application. As shown in FIG. 2, the SOP management method for the power battery pack of the present embodiment includes:

Step S110: obtaining the SOP value of each parallel battery branch in the power battery pack.

Specifically, obtaining the SOP value of the each parallel battery branch in the power battery pack in this embodiment can be understood as the secondary battery management unit of a branch obtains the SOP value of this branch and sends it to the primary battery management unit at system level, and can also be understood as the primary battery management unit at the system level obtains the SOP value of each parallel battery branch in the power battery pack. However, no matter what kind of understanding is made, the SOP value of each parallel battery branch is calculated by the secondary battery management unit that manages the branch, that is, the secondary battery management unit obtains the operating condition of the corresponding branch, and then through the operating condition of the branch gets the SOP value of the branch.

In one embodiment, obtaining the SOP value of the each parallel battery branch in the power battery pack includes:
obtaining an operating condition of the each parallel battery branch;
obtaining the SOP value of each parallel battery branch according to the operating condition and a corresponding SOP value reference table.

Specifically, when calculating the SOP value of the parallel battery branch, according to the battery temperature, SOC value and/or charge and discharge current of the parallel battery branch, the SOP reference value in the reference table is queried to obtain the corresponding SOP value. The SOP values of charge and discharge within a certain period of time are collected as SOP reference values in the reference table through conducting performance tests in advance on the battery. For details, please refer to FIG. 3, which is SOP reference table corresponding to temperature, SOC, and time in the embodiment of the present application. It is worth mentioning that the SOP value of the branch can also be calculated based on other operating conditions, not limited to the above temperature, SOC value and/or charge and discharge current.

In one embodiment, the step of obtaining the SOP value of the each parallel battery branch according to the operating condition and the corresponding SOP value reference table includes:
obtaining an initial SOP value of each parallel battery branch according to the operating condition and the corresponding SOP value reference table;
obtaining a fault level of each parallel battery branch;
performing power limiting processing on the initial SOP value of each parallel battery branch according to the fault level of each parallel battery branch, so as to obtain the SOP value of each parallel battery branch.

Specifically, in this embodiment, when obtaining the SOP value of each parallel battery branch, the fault condition of the branch is used as a reference factor, that is, the fault condition of the parallel battery branch is divided into multiple levels, and then, according to the fault level, the SOP value of each parallel battery branch is treated with power limiting. For example, the initial SOP value P1 of a parallel battery branch is obtained according to the operating condition and the corresponding SOP value reference table, and then the power limit is performed on the initial SOP value P1 of the parallel battery branch according to the fault level of the parallel battery branch. For example, according to the fault level, the SOP of the parallel battery branch needs to be limited, for example, to 70%, then the SOP value finally obtained by the parallel branch is the initial SOP value P1 multiplied by 70%.

It is worth mentioning that when performing power limiting, the power is limited by linear adjustment through multiple filtering processes. For example, the SOP value finally obtained by the parallel branch is the initial SOP value P1 multiplied by 70%, P1 multiplied by 70% is the final result, and the intermediate process is linear adjustment through filtering processes until the final result.

In one embodiment, the step of obtaining the fault level of each parallel battery branch includes:
obtaining a battery temperature and a battery voltage of each parallel battery branch;
obtaining the fault level of the each parallel battery branch according to the battery temperature and the battery voltage of the each parallel battery branch.

Specifically, the fault level can be obtained based on the battery under-temperature, under-voltage, overheat, overvoltage, and other battery status information. This fault level is not only used for the output of branch SOP, but also used for the primary battery management unit of the system to power off the seriously faulty branch, that is, the branch that has no power supply capacity.

Step S120: obtaining a current total SOP value of the power battery pack according to the SOP value of each parallel battery branch.

Specifically, after summarizing the SOP values of each parallel battery branch, the current total SOP value of the power battery pack is obtained through corresponding processing, which is output to the vehicle VCU (Vehicle Control Unit), and the fault information at system level can also be considered in the processing, which can effectively increase the safety and reliability of battery use.

In one embodiment, the step of obtaining the current total SOP value of the power battery pack according to the SOP values of each parallel battery branch includes;
obtaining the minimum value in the SOP values of each parallel battery branch;
obtaining the current total SOP value of the power battery pack according to the minimum value of the SOP values of the each parallel battery branch and number of the parallel branches in the power battery pack.

Specifically, in this embodiment, the minimum value of the SOP value of each parallel battery branch is obtained, and is used as the base value for calculating the current total SOP value, that is, the minimum value is multiplied by the number of branches of the parallel battery to obtain the current total SOP value of the power battery pack, which can ensure that the battery branches will not be overloaded under various operating conditions.

In one embodiment, the step of obtaining the current total SOP value of the power battery pack according to the minimum value of the SOP values of each parallel battery branch and the number of parallel branches in the power battery pack includes:
obtaining a first target total SOP value of the power battery pack through multiplying the minimum SOP value of the each parallel battery branch with the number of the parallel branches of the power battery pack;
obtaining the current total SOP value of the power battery pack through conducting filter processes for a last total SOP value of the power battery pack according to the first target total SOP value of the power battery pack.

Specifically, by obtaining the minimum value in the SOP values of the each parallel battery branch, and using this minimum value as the base value for calculating the total SOP value, that is, multiplying the minimum value by the number of branches of the parallel battery branch to obtain the first target total SOP value of the power battery pack. According to the first target total SOP value of the power battery pack, the last total SOP value of the power battery pack is filtered to obtain the current total SOP value of the power battery pack. In other words, the filter function is introduced to filter the last total SOP value according to the calculated first target total SOP value, so that the total SOP value changes smoothly, which make the overall SOP value change smoothly, so that sudden drop or surge of the current or power does not affect the operation of the load.

In one embodiment, a filtering process formula of filtering the last total SOP value of the power battery pack according to the first target total SOP value of the power battery pack is:

Z=δ*Z₀+(1−δ)*Z₁
where, Z is the current total SOP value of the power battery pack, Z₀ is a current first target total SOP value of the power battery pack, Z₁ is the last total SOP value of the power battery pack, and S is a preset coefficient.

Specifically, as the preset coefficient, S is 0.3. Of course, other values can also be selected according to the actual situation or performance requirements of the entire vehicle.

In one embodiment, the SOP management method for the power battery pack also includes:
obtaining a real-time charge and discharge current of the each parallel battery branch in the power battery pack;
adjusting the output of the parallel battery branch to the current SOP value of the branch, when the real-time charge and discharge current of one of the parallel battery branches is in an abnormal state, where the abnormal state includes that time period, during which the real-time charge and discharge current is greater than the SOP value of the branch under current parameter condition, reaches the first time value; or includes that time period, during which the real-time charge and discharge current is less than a preset ratio of the SOP value of the branch under the current parameter condition, reaches the second time value.

Specifically, the real-time charge and discharge current of each parallel battery branch is the current value actually measured at the battery input/output end through ammeters, etc. When it is lower than, for example, 90% of the continuous charge and discharge SOP reference value (continuous charge and discharge SOP reference value is the current value that the input/output terminal of the battery should have under the current parameter conditions), and the time period reaches 60 s. At this time, the actual situation of the vehicle can be a state of insufficient power supply for a period of time. The continuation of this state may cause part of functions of the vehicle fails due to insufficient power supply. At this time, the secondary battery management unit detects and judges the current allowable charge and discharge capacity of the parallel battery branch, and looks up the table to output the SOP reference value under the parameter conditions to the primary battery management unit, and then the primary battery management unit adjusts and increases the output of the parallel battery branch to the SOP reference value. When the real-time charge and discharge current of the parallel battery branch is higher than the continuous charge and discharge SOP reference value of the branch under the current parameter conditions for 15 s, the actual situation of the vehicle can be that the accelerator pedal is depressed for a long time, and if the output power of the vehicle is too high, it may lead to failures such as battery overheating. At this time, the secondary battery management unit detects and judges the current allowable charge and discharge capacity of the branch battery, and looks up the table to output the SOP reference value under the parameter conditions to the primary battery management unit. Further, the primary battery management unit reduces the output of the parallel battery branch to the SOP reference value.

The SOP management method for the power battery pack in this embodiment is to estimate in detail the SOP value of each parallel battery branch based on the operating conditions of each parallel battery branch in the power battery pack with multiple parallel branches, firstly, and then to estimate the total SOP of the power battery pack at the whole system level, and the problem of statistical distortion of the total SOP of the power battery pack is solved by the master-slave distinction. When calculating the SOP value of each parallel branch, through detecting the fault level of the each parallel branch, the SOP value of the branch is filtered and the power is limited according to the fault level, which effectively increases the safety of battery use. In addition, by detecting the actual output of the parallel battery branch, and comparing it with the obtained branch SOP value, the parallel battery branch can be prevented from running in an abnormal state for a long time and causing more serious faults, thus effectively reducing the fluctuation of the overall power supply to the vehicle, ensuring the smoothness of the vehicle and the effective utilization of energy.

### Second Embodiment

Please refer to FIG. 4, which is a schematic flowchart of an SOP management method for the power battery pack according to a second embodiment of the present application. The process shown in FIG. 4 is the process of updating the total SOP value when the vehicle is already in operation. As shown in FIG. 4, the SOP management method for the power battery pack of the present embodiment includes:

Step S210: obtaining an SOP value and a fault level of each parallel battery branch in a power battery pack.

Specifically, the fault level is obtained according to the operating conditions of the parallel battery branch, indicating the fault severity of the parallel battery branch. For example, it can be divided into 5 levels according to under temperature, under pressure, overheat, overpressure and other information. Each fault level has its corresponding fault processing methods. For example, when the fault level is 4, the SOP value of the branch can be filtered and the power value is limited to 50%, that is, based on obtaining the SOP value of the parallel battery branch through the operating conditions, limiting the SOP value of the parallel battery branch.

It should be noted that the fault level of the parallel battery branch is not only used for the secondary battery management unit of the parallel battery branch to obtain the SOP value of the parallel battery branch, but also needs to be sent to the primary battery management unit for the primary battery management unit to perform fault management.

Step S220: determining whether there is a parallel battery branch with serious faults.

Specifically, according to the fault level of each parallel battery branch, determining whether there is a parallel battery branch with serious faults, that is, determining whether there is a parallel battery branch that needs to be powered off according to the fault level of each parallel battery branch. For example, when the fault level of the parallel battery branch is level 5, the primary battery management unit needs to power it off. If the parallel battery branch needs to be powered off, it indicates that the parallel battery branch has a serious fault and cannot continue to supply power, and thus needs to be powered off to prevent the parallel battery branch from continuing to run in an abnormal state and causing more serious faults.

When there is no parallel battery branch with serious faults, proceeding with step S230: obtaining a second target total SOP value according to the minimum value of the SOP values of the parallel battery branches and the number of parallel battery branches.

Specifically, after determining that there is no parallel battery branch that needs to be powered off according to the fault level of each parallel battery branch, the second target total SOP value is obtained according to the minimum value of the obtained SOP value of the parallel battery branches and the number of parallel battery branches, that is, the second target total SOP value is obtained by multiplying the minimum SOP value of the SOP values of the parallel battery branches that are allowed to be powered on by the number of parallel battery branches that are allowed to be powered on.

Step S240: obtaining the fault level of the power battery pack.

Specifically, the fault level of the power battery pack refers to the fault at the system level of the entire power battery pack, which is a fault judgment at the overall level of the system made by the primary battery management unit based on information such as relay faults and current overcurrent faults in each branch.

It should be noted that, step S230 and step S240 may be performed simultaneously, or step S230 or step S240 may be performed before, which is not limited here.

Step S250: performing power limiting processing on the second target total SOP value according to the fault level of the power battery pack to obtain an updated second target total SOP value, and obtaining the current total SOP value of the power battery pack, through performing a corresponding filtering process on a last total SOP value of the power battery pack according to the updated second target total SOP value.

Specifically, since the operating conditions of the entire system are different from the operating conditions of a single branch, if a system-level fault occurs, when calculating the total SOP of the power battery pack, the main battery management unit, based on the power limiting of secondary battery management units in parallel battery branches, further limits the total SOP value, that is, the main battery management unit, according to the fault level of the power battery pack, performs the power limit on the second target total SOP value to obtain the updated second target total SOP value, and according to the updated second target total SOP value, performs a corresponding filtering process on a last total SOP value of the power battery pack. For example, the filtering processing formula is: Z=δ*Z₀+(1−δ)*Z₁, where Z is the current total SOP value of the power battery pack, Z₀ is the second target total SOP value of the current power battery pack, Z₁ is the last total SOP value of the power battery pack. The current total SOP value of the power battery pack is linearly adjusted by multiple filtering processes, to achieve power limiting and stable output.

This embodiment further includes that when there is a parallel battery branch with serious faults, proceeding with step S260: controlling the parallel battery branch with serious faults to be disconnected and powered off, and controlling the remaining parallel battery branches to output a preset total SOP value.

Specifically, when there is a parallel battery branch with serious faults, that is, when there is a parallel battery branch that needs to be powered off, controlling the parallel battery branch with serious faults to be disconnected and powered off, and controlling the remaining parallel battery branches to output the preset total SOP value. For example, when a branch has serious faults, the primary battery management unit will disconnect it and power it off, and control other parallel battery branches to output the SOP value of 20 A for guaranteed power supply. After the guaranteed power supply is completed, following the steps S210 to S250 of this embodiment, the primary battery management unit continues to calculate the total SOP value of the power battery pack and then adjusts the output value of the SOP according to the calculated value.

This embodiment further includes step S270: outputting the current total SOP value of the power battery pack.

Specifically, after the primary battery management unit has calculated the current total SOP value of the power battery pack, the current total SOP value is output to the VCU of the vehicle.

It is worth mentioning that, for other details in this embodiment, please refer to the first embodiment, which will not be repeated here.

The SOP management method for the power battery pack in this embodiment is to estimate in detail the SOP value of each parallel battery branch based on the operating conditions of each parallel battery branch in the power battery pack with multiple parallel branches, and then to estimate the total SOP of the power battery pack at the whole system level, and the problem of statistical distortion of the total SOP of the power battery pack is solved by the master-slave distinction. On the one hand, when calculating the SOP value of each parallel battery branch, through detecting the fault level of each parallel branch, the filtering processing and power limiting processing are applied to the branch SOP value according to the fault level. On the other hand, through detecting the fault at the system level of the power battery pack, further the power limiting processing is applied to the total SOP value according to the fault at the system level, which effectively increase the safety and stability of battery use.

### Third Embodiment

Please refer to FIG. 5. FIG. 5 is a schematic flowchart of an SOP management method for the power battery pack according to a third embodiment of the present application. The process shown in FIG. 5 is the process of obtaining and updating the total SOP value when the vehicle is powered on. As shown in FIG. 5, the SOP management method for the power battery pack of the present embodiment includes:

Step S310: obtaining the SOP value and fault level of each parallel battery branch in the power battery pack.

Specifically, the fault level is obtained according to the operating conditions of the parallel battery branch, indicating the fault severity of the parallel battery branch. For example, it can be divided into 5 levels according to under temperature, under pressure, overheat, overpressure and other information. Each fault level has corresponding fault processing methods. For example, when the fault level is 4, power limitation can be applied to the SOP value of the branch, and the power value is limited to 50%, that is, on the basis of obtaining the SOP value of the parallel battery branch through the operating conditions, limiting the SOP value of the parallel battery branch.

It should be noted that the fault level of the parallel battery branch is not only used for the secondary battery management unit of the parallel battery branch to obtain the SOP value of the parallel battery branch, but also needs to be sent to the primary battery management unit for the primary battery management unit to perform fault management.

Step S320: obtaining the current total SOP value according to the minimum value of the SOP values of the parallel battery branches and the number of parallel battery branches.

Specifically, in some cases, obtaining the SOP value of each parallel battery branch in the power battery pack is refreshed in real time, and in a power battery system with multiple parallel battery branches, the time for each parallel battery branch to obtain the SOP value may be different, and the time to send the obtained SOP values of each parallel battery branch to the primary battery management unit for calculating the total SOP value is also different, there is a sequence. However, the calculation of the total SOP value is updated in real time, so in this embodiment, steps S310 and S320 can be understood as the process of vehicle initialization.

Step S330: determining whether accumulated time is greater than a preset value.

Specifically, the accumulated time is the duration after the vehicle is powered on. The preset value is the maximum time for the secondary battery management unit to obtain the branch SOP value and fault level information under normal conditions. After the accumulated time reaches and is longer than the preset value, the process of vehicle initialization in the above steps S310 and S320 can be determined to be completed with certainty, that is, step S340 (and subsequent steps) can be proceeded with, and factor of the fault level is included to obtain and determine the overall SOP value. Generally, it is 100 ms˜1 s, or 300 ms. It is worth mentioning that, before step S320 is proceeded with step S330, outputting the current total SOP value of the power battery pack is also included. That is, in this embodiment, the total SOP value output during the initialization phase (before S330) and the total SOP value output during the subsequent normal operations (after S330) are not in conflict, and belong to two different phases. In other words, the first target total SOP value mentioned earlier above and the second target total SOP value mentioned later do not replace or affect each other, and are the intermediate values or reference values for calculating the current total SOP value in the two stages.

When the accumulated time is less than or equal to the preset value, returning to the step S320.

When the accumulated time is greater than the preset value, proceeding with the step S340: determining whether there is a parallel battery branch with serious faults in the power battery pack.

Specifically, when the accumulated time is greater than the preset value, determining whether there is a parallel battery branch with serious faults according to the fault level of each parallel battery branch, that is, determining whether there is a parallel battery that needs to be powered off according to the fault level of each parallel battery branch. For example, when the fault level of the parallel battery branch is level 5, the primary battery management unit needs to power off the parallel battery branch. If the parallel battery branch needs to be powered off, it indicates that there is a serious fault and it cannot continue to supply power. It needs to be powered off to prevent the parallel battery branch from continuing to run in an abnormal state and thus causing more serious faults.

When there is no parallel battery branch with serious faults, proceeding with the step S350: obtaining the second target total SOP value according to the minimum value of the SOP values of the parallel battery branch and the number of parallel battery branches.

Specifically, after determining that there is no parallel battery branch that needs to be powered off according to the fault level of each parallel battery branch, the second target total SOP value is obtained according to the minimum value of the obtained SOP values of the parallel battery branches and the number of parallel battery branches, that is, the second target total SOP value is obtained by multiplying the minimum SOP value of the SOP values of the parallel battery branches which are allowed to be powered on by the number of parallel battery branches which are allowed to be powered on. It is worth mentioning that steps after step S350 are the operation steps after the vehicle initialization is completed, that is, after the initialization is completed, the management method of the power battery pack SOP of this embodiment repeats the steps after step S350, to perform cyclic detection of the total SOP value. Obviously, when there is no the parallel battery branch with serious faults, obtaining the second target total SOP value according to the minimum value of the SOP values of the parallel battery branches and the number of parallel battery branches includes the process of continuously obtaining the SOP values of the parallel battery branches.

Step S360: obtaining the fault level of the power battery pack.

Specifically, the fault level of the power battery pack refers to the fault at the system level of the entire power battery pack, which is the fault judgment at the overall level of the system made by the primary battery management unit according to information such as relay faults and current overcurrent faults in each branch.

It should be noted that, step S360 and step S350 may be performed simultaneously, or step S350 or step S360 may be performed before, which is not limited.

Step S370: performing power limit processing on the second target total SOP value according to the fault level of the power battery pack to obtain the updated second target total SOP value, and performing a corresponding filtering process on a last total SOP value of the power battery pack according to the updated second target total SOP value, to obtain the current total SOP value of the power battery pack.

Specifically, since the operating conditions of the entire system are different from the operating conditions of a single branch, if a system-level fault occurs, when calculating the current total SOP of the power battery pack, on the basis of power limiting by secondary battery management units of parallel battery branches, the primary battery management unit further limits the current total SOP value, that is, filters the second target total SOP value according to the fault level of the power battery pack, to obtain the current total SOP value of the power battery pack after the power limiting processing. For example, the filtering process formula is: Z=δ*Z₀+(1−δ)*Z₁, where Z is the current total SOP value of the power battery pack, Z₀ is the second target total SOP value of the current power battery pack, and Z₁ is the last total SOP value of the current power battery pack. Thus through multiple filtering processes, the current total SOP value of the power battery pack is linearly adjusted, to achieve power limiting and stable output.

This embodiment also includes that when there is a parallel battery branch, proceeding with step S380: controlling the parallel battery branch with serious faults to be disconnected and powered off, and using the preset total SOP value as the current total SOP value of the power battery pack.

Specifically, when there is a parallel battery branch with serious fault, controlling the parallel battery branch with serious faults to power off, and controlling the remaining parallel battery branches to output a preset total SOP value, that is, using the preset total SOP value as the current total SOP value of the power battery pack.

This embodiment further includes step S390: outputting the current total SOP value of the power battery pack.

Specifically, after calculating the current total SOP value of the power battery pack, the primary battery management unit outputs it to the VCU of the vehicle.

The SOP management method for the power battery pack in this embodiment is to estimate in detail the SOP value of each parallel battery branch based on the operating conditions of each parallel battery branch in the power battery pack with multiple parallel branches, and then to estimate the total SOP of the power battery pack at the whole system level, and the problem of statistical distortion of the total SOP of the power battery pack is solved by the master-slave distinction. On the one hand, when calculating the SOP value of each parallel battery branch, through detecting the fault level of each parallel branch, the filtering processing and power limiting processing are applied to the branch SOP value according to the fault level. On the other hand, through detecting the fault at the system level of the power battery pack, further the power limiting processing is applied to the total SOP value according to the fault at the system level, which effectively increases the safety and stability of battery use. The SOP management method for the power battery pack in this embodiment can also calculate the total SOP value in real time in each use stage of the vehicle, and particularly can refresh in real time during the initialization process.

### Fourth Embodiment

The present application also provides an SOP management apparatus for the power battery pack. Please refer to FIG. 6, which is a schematic structural diagram of the SOP management apparatus for the power battery pack of the present application. As shown in FIG. 6, the SOP management apparatus of the power battery pack of the present application includes a primary battery management unit 13, that is, primary BMU, and a plurality of secondary battery management units 14, that is, secondary BMU, each secondary battery management unit 14 corresponds to a parallel battery branch, and the secondary battery management unit 14 obtains the operating condition information of cells in the battery module, such as temperature, voltage, etc., through the corresponding local control unit LECU (Local Electronic Control Unit). The primary battery management unit 13 is connected in communication with the secondary battery management unit 14. Each secondary battery management unit 14 is used to obtain the SOP value of the corresponding parallel battery branch in the power battery pack and send it to the primary battery management unit 13; the primary battery management unit 13 is used to obtain the current total SOP value of the power battery pack according to the SOP values of each parallel battery branches.

In one embodiment, each secondary battery management unit 14 is used to obtain the operating condition of the corresponding parallel battery branch, and obtain the SOP value of the corresponding parallel battery branch according to the operating condition and the corresponding SOP value reference table.

In one embodiment, each secondary battery management unit 14 is used to obtain an initial SOP value of the corresponding parallel battery branch according to the operating condition and the corresponding SOP value reference table, and then obtain the fault level of the corresponding parallel battery branch, and perform power limit processing on the initial SOP value of the corresponding parallel battery branch according to the fault level of the corresponding parallel battery branch, so as to obtain the SOP value of the corresponding parallel battery branch.

In one embodiment, each secondary battery management unit 14 is used to obtain the battery temperature and battery voltage of the corresponding parallel battery branch, and obtain the fault level of the corresponding parallel battery branch according to the battery temperature and battery voltage of the corresponding parallel battery branch.

In one embodiment, the primary battery management unit 13 is used to obtain the minimum value of the SOP values of each parallel battery branch, and obtain the current total SOP value of the power battery pack according to the minimum value of the SOP values of each parallel battery branch and the number of the parallel battery branches in the power battery pack.

In one embodiment, the primary battery management unit 13 is used to multiply the minimum value of the SOP values of each parallel battery branch by the number of parallel branches in the power battery pack to obtain the first target total SOP value of the power battery pack, and filtering the first target total SOP value of the power battery pack according to the first target total SOP value of the power battery pack to obtain the current total SOP value of the power battery pack.

In one embodiment, the filtering process formula is.

Z=δ*Z₀+(1−δ)*Z₁

Where, Z is the current total SOP value of the power battery pack, Z₀ is the first target total SOP value of the current power battery pack, Z₁ is the last total SOP value of the power battery pack, and o is a preset coefficient.

In one embodiment, the primary battery management unit 13 is also used to output the current total SOP value of the power battery pack, and when the accumulated time is greater than the preset value, the primary battery management unit 13 is also used to control the parallel battery branch with serious faults to be disconnected and powered off when there is an parallel battery branch with serious faults in the power battery pack, and to control the remaining parallel battery branches to output the preset total SOP value.

In one embodiment, the primary battery management unit 13 is also used to obtain the fault level of the power battery pack when the power battery pack does not include a parallel battery branch with serious faults, and obtain the second target total SOP value according to the minimum value of the SOP values of the online parallel battery branches and the number of the online parallel battery branches, and then obtain the updated second target total SOP value through performing the power limiting processing on the second target total SOP value according to the fault level of the power battery pack, and obtaining the current total SOP value of the power battery pack through performing the corresponding filtering process on the last total SOP value of the power battery pack according to the updated second target total SOP value.

In one embodiment, each secondary battery management unit 14 is also used to obtain the real-time charge and discharge current of each parallel battery branch in the power battery pack, and when the real-time charge and discharge current of one of the parallel battery branches is in an abnormal state, the secondary battery management unit 14 of the branch outputs the current SOP value of the parallel circuit branch to the primary battery management unit 13, and the primary battery management unit 13 adjusts the output of the parallel battery branch to the current SOP value, where the abnormal state includes that the time period, during which the real-time charge and discharge current is greater than the SOP value of this branch under the current parameter condition, reaches the first time value, or the time period, during which the real-time charge and discharge current is less than a preset ratio of the SOP value of the branch under the current parameter condition, reaches the second time value.

For details that are not specifically described in this embodiment, please refer to the foregoing embodiments, which will not be repeated here.

The SOP management apparatus for the power battery pack in this embodiment is to estimate in detail the SOP value of each parallel battery branch based on the operating conditions of each parallel battery branch in the power battery pack with multiple parallel branches, and then to estimate the total SOP of the power battery pack at the whole system level, and the problem of statistical distortion of the total SOP of the power battery pack is solved by the master-slave distinction. On the one hand, when calculating the SOP value of each parallel battery branch, through detecting the fault level of each parallel branch, the filtering processing and power limiting processing are applied to the branch SOP value according to the fault level. On the other hand, through detecting the fault at the system level of the power battery pack, further the power limiting processing is applied to the total SOP value according to the fault at the system level, which effectively increases the safety and stability of battery use.

The present application also provides an electric vehicle, which includes the SOP management apparatus for the power battery pack according to any one of the above embodiments. Of course, the vehicle may also include various network interfaces, power supplies and other components.

It should be noted that each embodiment in this specification is described in a progressive manner, and each embodiment focuses on the differences from other embodiments, and the same and similar parts between the various embodiments may be referred to each other.

The above-mentioned embodiments merely illustrate the principles and effects of the present application, but are not intended to limit the present application. Anyone skilled in the art can make modifications or changes to the above embodiments without departing from the spirit and scope of the present application. Therefore, all equivalent modifications or changes made by those with ordinary knowledge in the technical field without departing from the spirit and technical idea disclosed in the present application should still be covered by the claims of the present application.

### INDUSTRIAL APPLICABILITY

The SOP management method, apparatus and electric vehicle for the power battery pack of the present application are to estimate in detail the SOP value of each parallel battery branch based on the operating conditions of each parallel battery branch in the power battery pack with multiple parallel branches, and then to estimate the total SOP of the power battery pack at the whole system level, and the problem of statistical distortion of the total SOP of the power battery pack is solved by the master-slave distinction. On the one hand, when calculating the SOP value of each parallel battery branch, through detecting the fault level of each parallel branch, the filtering processing and power limiting processing are applied to the branch SOP value according to the fault level. On the other hand, through detecting the fault at the system level of the power battery pack, further the power limiting processing is applied to the total SOP value according to the fault at the system level, which effectively increases the safety and stability of battery use.

1. An SOP management method for a power battery pack, comprising the following steps:
obtaining an SOP value of each parallel battery branch in the power battery pack;
obtaining a current total SOP value of the power battery pack according to the SOP value of each parallel battery branch.

2. The SOP management method for the power battery pack as claimed in 1, wherein the step of obtaining the SOP value of each parallel battery branch in the power battery pack comprises:
obtaining an operating condition of the each parallel battery branch;
obtaining the SOP value of the each parallel battery branch according to the operating condition and a corresponding SOP value reference table.

3. The SOP management method for the power battery pack as claimed in 2, wherein the step of obtaining the SOP value of the each parallel battery branch according to the operating condition and the corresponding SOP value reference table comprises:
obtaining an initial SOP value of the each parallel battery branch according to the operating condition and the corresponding SOP value reference table;
obtaining a fault level of each parallel battery branch;
performing power limiting processing on the initial SOP value of the each parallel battery branch according to the fault level of the each parallel battery branch, so as to obtain the SOP value of the each parallel battery branch.

4. The SOP management method for the power battery pack as claimed in 3, wherein the step of obtaining the fault level of the each parallel battery branch comprises:
obtaining a battery temperature and a battery voltage of the each parallel battery branch;
obtaining the fault level of the each parallel battery branch according to the battery temperature and the battery voltage of the each parallel battery branch.

5. The SOP management method for the power battery pack according to claim 1, wherein the step of obtaining the current total SOP value of the power battery pack according to the SOP value of the each parallel battery branch comprises:
obtaining the minimum value in the SOP value of the each parallel battery branch;
obtaining the current total SOP value of the power battery pack according to the minimum value of the SOP value of the each parallel battery branch and number of the parallel branches in the power battery pack.

6. The SOP management method for the power battery pack as claimed in 5, wherein after the step of obtaining the current total SOP value of the power battery pack according to the minimum value of the SOP value of the each parallel battery branch and the number of the parallel branches in the power battery pack, the method further comprises:
determining whether the power battery pack has a parallel battery branch with serious faults;
when there is a parallel battery branch with serious faults in the power battery pack, disconnecting the parallel battery branch with serious faults, and controlling the remaining parallel battery branches to output a preset total SOP value.

7. The SOP management method for the power battery pack as claimed in 5, wherein the step of obtaining the current total SOP value of the power battery pack according to the minimum value of the SOP value of the each parallel battery branch and the number of the parallel branches in the power battery pack comprises:
obtaining a first target total SOP value of the power battery pack through multiplying the minimum SOP value of the each parallel battery branch and the number of the parallel branches of the power battery pack;
obtaining the current total SOP value of the power battery pack through filtering a last total SOP value of the power battery pack according to the first target total SOP value of the power battery pack.

8. The SOP management method for the power battery pack as claimed in 7, wherein a filtering process formula of filtering the last total SOP value of the power battery pack according to the first target total SOP value of the power battery pack is:
Z=δ*Z₀+(1−δ)*Z₁
wherein, Z is the current total SOP value of the power battery pack, Z₀ is a current first target total SOP value of the power battery pack, Z₁ is the last total SOP value of the power battery pack, and δ is a preset coefficient.

9. The SOP management method for the power battery pack as claimed in 5, wherein after the step of obtaining the current total SOP value of the power battery pack according to the minimum value of the SOP value of the each parallel battery branch and the number of the parallel branches in the power battery pack, the method further comprises:
outputting the current total SOP value of the power battery pack;
determining whether accumulated time is greater than a preset value;
when the accumulated time is greater than the preset value, determining whether the power battery pack has a parallel battery branch with serious faults;
when there is a parallel battery branch with serious faults in the power battery pack, disconnecting the parallel battery branch with serious faults, and controlling remaining parallel battery branches to output a preset total SOP value.

10. The SOP management method for the power battery pack as claimed in 6, wherein the SOP management method for the power battery pack further comprises:
obtaining a fault level of the power battery pack when there is no parallel battery branch with serious faults in the power battery pack;
obtaining a second target total SOP value according to the minimum value of SOP values of online parallel battery branches and number of the online parallel battery branches;
performing power limiting processing on the second target total SOP value according to the fault level of the power battery pack to obtain an updated second target total SOP value;
performing a corresponding filtering process on a last total SOP value of the power battery pack according to the updated second target total SOP value, to obtain the current total SOP value of the power battery pack.

11. The SOP management method for the power battery pack as claimed in 1, wherein the SOP management method for the power battery pack further comprises:
obtaining a real-time charge and discharge current of the each parallel battery branch in the power battery pack;
adjusting the output of the parallel battery branch to the current SOP value of the branch, when the real-time charge and discharge current of one of the parallel battery branches is in an abnormal state, wherein the abnormal state comprises that time period, during which the real-time charge and discharge current is greater than the SOP value of the branch under current parameter condition, reaches a first time value; or comprises that time period, during which the real-time charge and discharge current is less than a preset ratio of the SOP value of the branch under the current parameter condition, reaches a second time value.

12. An SOP management apparatus for a power battery pack, wherein the apparatus comprises a primary battery management unit and a plurality of secondary battery management units, the primary battery management unit and the plurality of secondary battery management units are connected in communication, wherein,
each secondary battery management unit is configured to obtain an SOP value of the corresponding parallel battery branch in the power battery pack and send it to the primary battery management unit;
the primary battery management unit is configured to obtain a current total SOP value of the power battery pack according to the SOP value of each parallel battery branch.

13. An electric vehicle, comprising the SOP management apparatus for the power battery pack as claimed in claim 12.

14. The SOP management method for the power battery pack as claimed in 2, wherein the step of obtaining the current total SOP value of the power battery pack according to the SOP value of the each parallel battery branch comprises:
obtaining the minimum value in the SOP value of the each parallel battery branch;
obtaining the current total SOP value of the power battery pack according to the minimum value of the SOP value of the each parallel battery branch and number of the parallel branches in the power battery pack.

15. The SOP management method for the power battery pack as claimed in 3, wherein the step of obtaining the current total SOP value of the power battery pack according to the SOP value of the each parallel battery branch comprises:
obtaining the minimum value in the SOP value of the each parallel battery branch;
obtaining the current total SOP value of the power battery pack according to the minimum value of the SOP value of the each parallel battery branch and number of the parallel branches in the power battery pack.

16. The SOP management method for the power battery pack as claimed in 4, wherein the step of obtaining the current total SOP value of the power battery pack according to the SOP value of the each parallel battery branch comprises:
obtaining the minimum value in the SOP value of the each parallel battery branch;
obtaining the current total SOP value of the power battery pack according to the minimum value of the SOP value of the each parallel battery branch and number of the parallel branches in the power battery pack.

17. The SOP management method for the power battery pack as claimed in 6, wherein the step of obtaining the current total SOP value of the power battery pack according to the minimum value of the SOP value of the each parallel battery branch and the number of the parallel branches in the power battery pack comprises:
obtaining a first target total SOP value of the power battery pack through multiplying the minimum SOP value of the each parallel battery branch and the number of the parallel branches of the power battery pack;
obtaining the current total SOP value of the power battery pack through filtering a last total SOP value of the power battery pack according to the first target total SOP value of the power battery pack.

18. The SOP management method for the power battery pack as claimed in 7, wherein after the step of obtaining the current total SOP value of the power battery pack according to the minimum value of the SOP value of the each parallel battery branch and the number of the parallel branches in the power battery pack, the method further comprises:
outputting the current total SOP value of the power battery pack;
determining whether accumulated time is greater than a preset value;
when the accumulated time is greater than the preset value, determining whether the power battery pack has a parallel battery branch with serious faults;
when there is a parallel battery branch with serious faults in the power battery pack, disconnecting the parallel battery branch with serious faults, and controlling remaining parallel battery branches to output a preset total SOP value.

19. The SOP management method for the power battery pack as claimed in 9, wherein the SOP management method for the power battery pack further comprises:
obtaining a fault level of the power battery pack when there is no parallel battery branch with serious faults in the power battery pack;
obtaining a second target total SOP value according to the minimum value of SOP values of online parallel battery branches and number of the online parallel battery branches;
performing power limiting processing on the second target total SOP value according to the fault level of the power battery pack to obtain an updated second target total SOP value;
performing a corresponding filtering process on a last total SOP value of the power battery pack according to the updated second target total SOP value, to obtain the current total SOP value of the power battery pack.
